(19) United States
(12) Patent Application Publication
(10) Pub. No.: US 2018/0335695 A1
(43) Pub. Date: Nov. 22, 2018

(54) PHOTOSENSITIVE RESIN COMPOSITION AND ORGANIC INSULATING FILM PREPARED THEREFROM

(71) Applicant: Rohm and Haas Electronic Materials Korea Ltd., Cheonan (KR)

(72) Inventors: Yu-Jin Chae, Hwaseong (KR); Ju-Young Jung, Hwaseong (KR); Seung-Ho Kwon, Hwaseong (KR); Jung-Hwa Lee, Hwaseong (KR); Seung-Keun Kim, Hwaseong (KR)

(21) Appl. No.: 15/777,752

(22) PCT Filed: Oct. 4, 2016
(86) PCT No.: PCT/KR2016/011064

§ 371 Date: May 21, 2018

(30) Foreign Application Priority Data
Dec. 3, 2015 (KR) 10-2015-0171318

(51) Int. Cl. G03F 7/033; G03F 7/031; C08F 212/08; H01B 17/56; H01B 3/44

(52) U.S. Cl. CPC G03F 7/033; G03F 7/031; C08F 2800/10; H01B 17/56; H01B 3/44; C08F 212/08

(57) ABSTRACT

Disclosed herein are a photosensitive resin composition and an organic insulating film prepared therefrom. By optimizing the weight average molecular weight of an alkali-soluble resin and the amount of each component in the photosensitive resin composition, a coated film obtained therefrom may have high planarity property and patterns with high resolution. Accordingly, the photosensitive resin composition may be used as a material for an organic insulating film simultaneously functioning as white pixels in a liquid crystal display.

### TECHNICAL FIELD

The present invention relates to a photosensitive resin composition and an organic insulating film prepared therefrom, in particular a negative-type photosensitive resin composition for the formation of a film having patterns with high planarity and high resolution, and an organic insulating film prepared using same, which can simultaneously function as white pixels in a liquid crystal display.

### BACKGROUND ART

In a display such as a thin film transistor (TFT)-type liquid crystal display, an organic insulating film is used to protect and insulate TFT circuits. Recently, in order to meet the high resolution requirement for a display, the size of pixels tends to gradually decrease, which may cause undesirable decrease of an aperture ratio. In order to resolve this problem, a white pixel in addition to blue, green and red pixels is introduced in a display. In such case, however, an additional process for introducing white pixels is required.

Accordingly, a method for introducing white pixels by using an organic insulating film receives much attention. That is, after the formation of a colored film on a part of a substrate, a composition for a transparent organic insulating film is coated on the entire substrate having both of a region where the colored film is formed and a region where the colored film is not formed, and then cured. In the region where the colored film is not formed, the cured film may function as both white pixels and an organic insulating film. In this method, however, due to the height difference between the region with the colored film and the region without the colored film, the surface of the organic insulating film is unevenly formed, thereby increasing defects in a liquid crystal display.

Among various compositions that may be used for preparing a film having both functions of a white pixel and a protective film, Korean Patent No. 10-1336305 discloses a resin composition for a thermosetting protective film comprising a binder resin having a weight average molecular weight of 5,000 to 10,000, a polyfunctional monomer and other additives. However, the composition of this patent, which corresponds to a thermosetting resin composition, is not a photosensitive resin composition including a photopolymerization initiator, and a film prepared by using this composition cannot have high resolution patterns due to the difficulty in forming patterns.

### DISCLOSURE OF INVENTION

### Technical Problem

An object of the present invention is to provide a photosensitive resin composition which may produce patterns satisfying both high planarity and high resolution, and an organic insulating film manufactured therefrom.

### Solution to Problem

According to one aspect of the present invention, there is provided a photosensitive resin composition, comprising: (1) an alkali-soluble resin having a weight average molecular weight of 1,000 to 5,000; (2) a photopolymerizable compound; and (3) a photopolymerization initiator; wherein the components (1), (2) and (3) are included in the photosensitive resin composition in amounts of 3 to 48 wt %, 50 to 95 wt %, and 0.5 to 15 wt %, respectively, based on a total solid content of the photosensitive resin composition.

In addition, there is provided an organic insulating film formed using the photosensitive resin composition.

### Advantageous Effects of Invention

The photosensitive resin composition of the present invention may produce a film having patterns of high planarity and high resolution, and may be used as a material for an organic insulating film, etc. and is appropriate for accomplishing both functions of an organic insulating film and a white pixel in a liquid crystal display.

### BRIEF DESCRIPTION OF DRAWINGS

FIG. 1 illustrates a method of measuring the planarity of an organic insulating film manufactured using a photosensitive resin composition (10: organic insulating film, 20: lower cured film, and 30: substrate).

### BEST MODE FOR CARRYING OUT THE INVENTION

The present invention provides a photosensitive resin composition, which comprises (1) an alkali-soluble resin having a weight average molecular weight of 1,000 to 5,000; (2) a photopolymerizable compound; and (3) a photopolymerization initiator; wherein the components (1), (2) and (3) are included in the photosensitive resin composition in amounts of 3 to 48 wt %, 50 to 95 wt %, and 0.5 to 15 wt %, respectively, based on a total solid content of the photosensitive resin composition.

Hereinafter, the photosensitive resin composition will be explained in detail.

In the present description, “(meth)acryl” means “acryl” and/or “methacryl”, and “(meth)acrylate” means “acrylate” and/or “methacrylate”.

(1) Alkali-Soluble Resin

The photosensitive resin composition of the present invention may include an alkali-soluble resin, which may be a random copolymer.

The alkali-soluble resin may be a copolymer including (1-1) a structural unit derived from an ethylenically unsaturated carboxylic acid, an ethylenically unsaturated carboxylic anhydride or a mixture thereof, and (1-2) a structural unit derived from an ethylenically unsaturated compound containing an aromatic ring, and may selectively includes (1-3) a structural unit derived from an ethylenically unsaturated compound different from the structural units (1-1) and (1-2). The alkali-soluble resin may achieve desired developability during the development step and may function as both of a basic support for forming a film after coating and a structure for final patterns.

(1-1) Structural Unit Derived from an Ethylenically Unsaturated Carboxylic Acid, an Ethylenically Unsaturated Carboxylic Anhydride, or a Mixture Thereof

In the present invention, the structural unit (1-1) is derived from an ethylenically unsaturated carboxylic acid, an ethylenically unsaturated carboxylic anhydride, or a mixture thereof. The ethylenically unsaturated carboxylic acid, the ethylenically unsaturated carboxylic anhydride, or the mixture thereof is a polymerizable unsaturated monomer having at least one carboxyl group in a molecule. Examples thereof include an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono[2-(meth)acryloyloxyethyl] succinate, and mono[2-(meth)acryloyloxyethyl] phthalate, but are not limited thereto. In terms of developability, (meth)acrylic acid is preferred among them.

The amount of the structural unit (1-1) derived from an ethylenically unsaturated carboxylic acid, an ethylenically unsaturated carboxylic anhydride, or a mixture thereof may be 5 to 98 mole %, preferably 15 to 50 mole % based on the total number of moles of the structural units constituting the alkali-soluble resin to maintain good developability.

(1-2) Structural Unit Derived from an Ethylenically Unsaturated Compound Containing an Aromatic Ring

In the present invention, the structural unit (1-2) is derived from an ethylenically unsaturated compound containing an aromatic ring, and examples of the ethylenically unsaturated compound containing an aromatic ring may be at least one selected from the group consisting of phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate; styrene; styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene having halogen such as fluorostyrene, chlorostyrene, bromostyrene, and iodostyrene; styrene having an alkoxy substituent such as methoxystyrene, ethoxystyrene, and propoxystyrene; 4-hydroxy styrene, p-hydroxy-α-methylstyrene, acetylstyrene; vinyltoluene, divinylbenzene, vinylphenol, o-vinylbenzyl methyl ether, m-vinylbenzyl methyl ether, p-vinylbenzyl methyl ether, o-vinylbenzyl glycidyl ether, m-vinylbenzyl glycidyl ether, and p-vinylbenzyl glycidyl ether, and preferably, may be styrene compounds in consideration of polymerization properties.

The amount of the structural unit (1-2) derived from an ethylenically unsaturated compound containing an aromatic ring may be 2 to 95 mole %, preferably 10 to 60 mole % in consideration of chemical resistance, based on the total number of moles of the structural units constituting the alkali-soluble resin.

The alkali-soluble resin of the present invention may additionally include a structural unit (1-3) derived from an ethylenically unsaturated compound different from the structural units (1-1) and (1-2).

(1-3) Structural Unit Derived from an Ethylenically Unsaturated Compound Different from the Structural Units (1-1) and (1-2)

In the present invention, the structural unit (1-3) is derived from an ethylenically unsaturated compound different from the structural units (1-1) and (1-2), and the ethylenically unsaturated compound different from the structural units (1-1) and (1-2) may be at least one selected from the group consisting of an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl-α-hydroxymethylacrylate, ethyl-α-hydroxymethylacrylate, propyl-α-hydroxymethylacrylate, butyl-α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; an ethylenically unsaturated compound containing an epoxy group such as glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, and 3,4-epoxycyclohexyl (meth)acrylate; a tertiary amine containing an N-vinyl group such N-vinyl pyrrolidone, N-vinyl carbazole and N-vinyl morpholine; an unsaturated ether such as vinyl methyl ether and vinyl ethyl ether; an unsaturated ether containing an epoxy group such as allyl glycidyl ether, and 2-methylallyl glycidyl ether; and an unsaturated imide such as maleimide, N-phenylmaleimide, N-(4-chlorophenyl)maleimide, N-(4-hydroxyphenyl)maleimide and N-cyclohexylmaleimide. Particularly, the structural unit (1-3) may be an ethylenically unsaturated compound containing an epoxy group in consideration of the improvement of copolymerization properties and the strength of an insulating film, preferably, methyl (meth)acrylate, glycidyl (meth)acrylate, 4-hydroxybutyl acrylate glycidyl ether, or 3,4-epoxycyclohexyl (meth)acrylate. More preferably, 3,4-epoxycyclohexyl (meth)acrylate may be used in consideration of chemical resistance and retention rate.

The amount of the structural unit (1-3) derived from an ethylenically unsaturated compound different from the structural units (1-1) and (1-2) may be 0 to 75 mole %, preferably 10 to 65 mole %, based on the total number of moles of the structural units constituting the alkali-soluble resin. Within this amount range, the storage stability of a composition may be maintained and the retention rate may be improved.

The alkali-soluble resin (1) may include a (meth)acrylic acid/styrene copolymer, a (meth)acrylic acid/benzyl (meth)acrylate copolymer, a (meth)acrylic acid/styrene/methyl (meth)acrylate copolymer, a (meth)acrylic acid/styrene/methyl (meth)acrylate/glycidyl methacrylate copolymer, a (meth)acrylic acid/styrene/methyl (meth)acrylate/3,4-epoxycyclohexyl (meth)acrylate copolymer, a (meth)acrylic acid/styrene/methyl (meth)acrylate/4-hydroxybutylacrylate glycidyl ether copolymer, a (meth)acrylic acid/styrene/methyl (meth)acrylate/glycidyl methacrylate/3,4-epoxycyclohexyl (meth)acrylate copolymer, a (meth)acrylic acid/styrene/methyl (meth)acrylate/4-hydroxybutylacrylate glycidyl ether/3,4-epoxycyclohexyl (meth)acrylate copolymer, a (meth)acrylic acid/styrene/methyl (meth)acrylate/glycidyl methacrylate/N-phenylmaleimide copolymer, a (meth)acrylic acid/styrene/methyl (meth)acrylate/glycidyl methacrylate/N-cyclohexyl maleimide copolymer, a (meth)acrylic acid/styrene/n-butyl (meth)acrylate/glycidyl methacrylate/N-phenyl maleimide copolymer, or a mixture thereof. One or more alkali-soluble resins may be included in the photosensitive resin composition.

The alkali-soluble resin (1) may be prepared by charging a molecular weight regulator, a radical polymerization initiator, a solvent, and respective compounds that provide the structural units (1-1), (1-2), and (1-3), introducing nitrogen, and subjecting the mixture to polymerization with slow agitation. The alkali-soluble resin (1) may be prepared as a random copolymer.

The molecular weight regulator may be a mercaptan compound such as butyl mercaptan and octyl mercaptan, or an α-methylstyrene dimer, but is not limited thereto.

The radical polymerization initiator may be at least one selected from the group consisting of an azo compound such as 2,2′-azobisisobutyronitrile, 2,2′-azobis(2,4-dimethylvaleronitrile), and 2,2′-azobis(4-methoxy-2,4-dimethylvaleronitrile), benzoyl peroxide, lauryl peroxide, t-butyl peroxypivalate and 1,1-bis(t-butylperoxy)cyclohexane, but is not limited thereto.

Also, the solvent may be any conventional solvent commonly used in the manufacturing of an alkali-soluble resin and may include, e.g., methyl 3-methoxypropionate or propylene glycol monomethyl ether acetate (PGMEA).

The alkali-soluble resin (1) may be used in an amount of 3 to 48 wt %, preferably 8 to 38 wt %, based on a total solid content of the photosensitive resin composition excluding solvents. Within this range, the composition would produce a patterned film having a good profile after development with improved properties such as retention rate, and chemical resistance.

The weight average molecular weight (Mw) of the alkali-soluble resin (1) thus prepared may be in the range of 1,000 to 5,000, preferably 3,000 to 5,000, when determined by gel permeation chromatography (GPC, using tetrahydrofuran as an eluent) referenced to polystyrene. Within this range, the composition would have desirable improvements in planarity and a good pattern profile after development.

(2) Photopolymerizable Compound

The photosensitive resin composition of the present invention may include a photopolymerizable compound.

The photopolymerizable compound may be any compound to be polymerized by a polymerization initiator and may be a monofunctional or polyfunctional ester compound of acrylic acid or methacrylic acid having at least one ethylenically unsaturated group. A polyfunctional compound having at least two functional groups may be preferred in consideration of chemical resistance.

The photopolymerizable compound may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, monoester of pentaerythritol tri(meth)acrylate and succinic acid, pentaerythritol tetra(meth)acrylate, dipentaerythritol penta(meth)acrylate, dipentaerythritol hexa(meth)acrylate, monoester of dipentaerythritol penta(meth)acrylate and succinic acid, caprolactone modified dipentaerythritol hexa(meth)acrylate, pentaerythritol triacrylate hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but is not limited thereto.

Besides the above examples, the photopolymerizable compound may be a polyfunctional urethane acrylate compound obtained from the reaction of a compound having a straight chain alkylene group, an alicyclic structure and at least two isocyanate groups, and a compound having at least one hydroxyl group in a molecule, three, four or five acryloyloxy groups and/or methacryloyloxy groups, but is not limited thereto.

Examples of commercially available photopolymerizable compounds may include (i) monofunctional (meth)acrylate such as Aronix M-101, M-111, and M-114 manufactured by Toagosei Co., Ltd., KAYARAD T4-110S, and T4-120S manufactured by Nippon Kayaku Co., Ltd., and V-158, and V-2311 manufactured by Osaka Yuki Kagaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kagaku Kogyo Co., Ltd.; and (iii) tri and more functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA, V-400, and V-802 manufactured by Osaka Yuki Kagaku Kogyo Co., Ltd.

The photopolymerizable compound (2) may be used alone or in combination of two or more thereof.

The amount of the photopolymerizable compound (2) may be 50 to 95 wt %, preferably 60 to 90 wt %, based on a total solid content of the photosensitive resin composition. Within this range, the resin composition would form a film having good sensitivity and planarity.

(3) Photopolymerization Initiator

The photopolymerization initiator of the present invention may be a compound that initiates polymerization of curable monomers upon exposure to light such as visible rays, ultraviolet rays, and deep-ultraviolet radiation. The photopolymerization initiator may be a radical initiator, which is not specifically limited but may be at least one selected from the group consisting of an acetophenone compound, a benzophenone compound, a benzoin compound, a benzoyl compound, a xanthone compound, a triazine compound, a halomethyloxadiazole compound, and a lophine dimer compound.

Particular examples of the photopolymerization initiator may include, but are not limited to, 2,2′-azobis(2,4-dimethylvaleronitrile), 2,2′-azobis(4-methoxy-2,4-dimethylvaleronitrile), benzoyl peroxide, lauryl peroxide, t-butyl peroxypivalate, 1,1-bis(t-butyl peroxy)cyclohexane, p-dimethylamino acetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthone, 2,4-bis(trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, a 2-(o-chlorophenyl)-4,5-diphenylimidazolyl dimer, 1-phenyl-1,2-propanedione-2-(o-ethoxycarbonyl)oxime, 1-[4-(phenylthio)phenyl]-octane-1,2-dione-2-(0-benzoyloxime), o-benzoyl-4′-(benzmercapto)benzoyl-hexyl-ketoxime, 2,4,6-trimethylphenylcarbonyl-diphenylphosphonyloxide, hexafluorophosphoro-trialkylphenyl sulfonium salt, 2-mercaptobenzimidazole, 2,2′-benzothiazolyl disulfide, and a mixture thereof. Alternatively, the photopolymerization initiator may include at least one kind of an oxime compound. The oxime compound may include any radical initiator having an oxime structure without specific limitation, and may include, e.g., an oxime ester compound.

Preferred for high sensitivity are one or more oxime compounds disclosed in Korean Laid-open Patent Publication Nos. 2004-0007700, 2005-0084149, 2008-0083650, 2008-0080208, 2007-0044062, 2007-0091110, 2007-0044753, 2009-0009991, 2009-0093933, 2010-0097658, 2011-0059525, 2011-0091742, 2011-0026467, and 2011-0015683, and PCT Publication Nos. WO2010/102502 and WO2010/133077 in consideration of high sensitivity. Particular examples of commercially available photopolymerization initiators include OXE-01 (BASF Co.), OXE-02 (BASF Co.), OXE-03 (BASF Co.), N-1919 (ADEKA Co.), NCI-930 (ADEKA Co.), NCI-831 (ADEKA Co.), or the like.

The photopolymerization initiator (3) may be included in an amount of 0.5 to 15 wt %, preferably 1 to 10 wt %, based on a total solid content of the photosensitive resin composition. Within this range, highly sensitive patterns having good pattern developability and coatability may be obtained.

(4) Solvent

The photosensitive resin composition of the present invention may be prepared by mixing the above components with the solvent (4) to obtain a liquid-phase composition.

The solvent (4) is not limited as long as it is compatible with each component of the composition and chemically stable, and any known solvent used in a photosensitive resin composition may be used.

Examples of the solvent may include ethylene glycol monoalkyl ether acetates such as ethylene glycol monomethyl ether acetate, and ethylene glycol monoethyl ether acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol dipropyl ether, and propylene glycol dibutyl ether; dipropylene glycol dialkyl ethers such as dipropylene glycol dimethyl ether; propylene glycol monoalkyl ether acetates such as propylene glycol monomethyl ether acetate, propylene glycol monoethyl ether acetate, propylene glycol monopropyl ether acetate, and propylene glycol monobutyl ether acetate; cellosolves such as ethyl cellosolve and butyl cellosolve; carbitols such as butyl carbitol; lactic acid esters such as methyl lactate, ethyl lactate, n-propyl lactate, and isopropyl lactate; aliphatic carboxylates such as ethyl acetate, n-propyl acetate, isopropyl acetate, n-butyl acetate, isobutyl acetate, n-amyl acetate, isoamyl acetate, isopropyl propionate, n-butyl propionate, and isobutyl propionate; esters such as methyl 3-methoxyprioipnate, ethyl 3-methoxypropionate, methyl 3-ethoxypropionate, ethyl 3-ethoxypropionate, methyl pyruvate, and ethyl pyruvate; aromatic hydrocarbons such as toluene and xylene; ketones such as 2-heptanone, 3-heptanone, 4-heptanone, and cyclohexanone; imides such as N-dimethylformamide, N-methyl acetamide, N,N-dimethyl acetamide, and N-methyl pyrrolidone; lactones such as γ-butyrolactone; and a mixture thereof, but is not limited thereto.

The solvents may be used alone or in combination of two or more thereof.

The amount of the solvent (4) in the photosensitive resin composition of the present invention is not specifically limited. For the good coatability and stability of the photosensitive resin composition, the solvent may be contained in an amount such that the solid content of the composition ranges from 5 to 70 wt %, preferably 10 to 55 wt %, based on a total weight of the composition. Here, the solid content means the amount of the components excluding the solvents in the resin composition.

(5) Surfactant

The photosensitive resin composition of the present invention may further include a surfactant as occasion demands to enhance its coatability and to prevent the formation of defects.

The surfactants are not limited, but preferred are fluorine-based surfactants, silicon-based surfactants, non-ionic surfactant and the like.

Examples of the surfactants may include fluorine- and silicon-based surfactants such as BM-1000, and BM-1100 manufactured by BM CHEMIE Co., Ltd., Megapack 6-142 D, 6-172, 6-173, 6-183, F-470, F-471, F-475, F-482, and F-489 manufactured by Dai Nippon Ink Kagaku Kogyo Co., Ltd., Florad F4-135, F4-170 C, FC-430, and FC-431 manufactured by Sumitomo 3M Ltd., Sufron S-112, S-113, S-131, S-141, S-145, S-382, S4-101, S4-102, S4-103, S4-104, S4-105, and S4-106 manufactured by Asahi Glass Co., Ltd., Eftop EF301, EF303, and EF352 manufactured by Shinakida Kasei Co., Ltd., SH-28 PA, SH-190, SH-193, SZ-6032, SF-8428, DC-57, and D4-190 manufactured by Toray Silicon Co., Ltd., DC3PA, DC7PA, SH11PA, SH21PA, SH8400, FZ-2100, FZ-2110, FZ-2122, FZ-2222, and FZ-2233 manufactured by Dow Corning Toray Silicon Co., Ltd., TSF-4440, TSF-4300, TSF-4445, TSF-4446, TSF-4460, and TSF-4452 manufactured by GE Toshiba Silicon Co., Ltd., and BYK-333 manufactured by BYK Co., Ltd.; non-ionic surfactants such as polyoxyethylene alkyl ethers including polyoxyethylene lauryl ether, polyoxyethylene stearyl ether, polyoxyethylene oleyl ether, or the like, polyoxyethylene aryl ethers including polyoxyethylene octylphenyl ether, polyoxyethylene nonylphenyl ether, or the like, and polyoxyethylene dialkyl esters including polyoxyethylene dilaurate, polyoxyethylene distearate, or the like; and organosiloxane polymer KP341 (manufactured by Shin-Etsu Kagaku Kogyo Co., Ltd.), (meth)acrylate-based copolymer Polyflow No. 57 and 95 (Kyoei Yuji Kagaku Kogyo Co., Ltd.), and the like

These surfactants may be used alone or in combination of two or more thereof.

The surfactant (5) may be contained in an amount of 0.001 to 2.5 wt %, preferably 0.025 to 0.5 wt %, based on a total solid content of the photosensitive resin composition. Within this amount range, the composition can be readily coated.

(6) Adhesion Assisting Agent

The photosensitive resin composition of the present invention may additionally include an adhesion assisting agent to improve the adhesiveness of a coating to a substrate.

The adhesion assisting agent is not limited to specific kinds, however may include, e.g., a silane coupling agent containing at least one reactive group selected from the group consisting of a carboxyl group, a (meth)acryloyl group, an isocyanate group, an amino group, a mercapto group, a vinyl group and an epoxy group.

Preferred adhesion assisting agent may include trimethoxysilyl benzoic acid, γ-methacryloxypropyltrimethoxysilane, vinyltriacetoxysilane, vinyltrimethoxysilane, γ-isocyanatopropyltriethoxysilane, γ-isocyanatepropyltriethoxysilane, γ-glycidoxypropyltrimethoxysilane, γ-glycidoxypropyltriethoxysilane, N-phenylaminopropyltrimethoxysilane, β-(3,4-epoxycyclohexyl)ethyltrimethoxysilane, or a mixture thereof, and more preferably may include γ-glycidoxypropyltriethoxysilane, γ-glycidoxypropyltrimethoxysilane, N-phenylaminopropyltrimethoxysilane, or the like, which may increase retention rate and have good adhesiveness of a coating to a substrate. In addition, γ-isocyanatopropyltriethoxysilane containing an isocyanate group (e.g., KBE-9007 manufactured by Shin-Etsu Co., Ltd.) may be used to improve chemical resistance.

The adhesion assisting agent (6) may be contained in an amount of 0.001 to 2.5 wt %, preferably 0.025 to 0.5 wt % based on a total solid content of the photosensitive resin composition. Within this amount range, the adhesiveness of a coating to a substrate may be further improved.

Besides the above components, the photosensitive resin composition of the present invention may further include other additives such as an antioxidant, a stabilizer, and a radical capture as long as the physical properties of the composition are not adversely affected.

The photosensitive resin composition of the present invention may be used as a negative-type photosensitive resin composition. Particularly, the photosensitive resin composition may be coated on a substrate and cured to produce an insulating film.

The insulating film may be manufactured by a conventional method well known in the art. For instance, the photosensitive resin composition may be coated on a silicon substrate by a spin coating method; subjected to pre-bake at a temperature of, e.g., 60 to 130° C. for 60 to 130 seconds to remove the solvents; exposed to light using a photomask having a desired pattern; and subjected to development using a developing agent, for example, a tetramethylammonium hydroxide (TMAH) solution, to form a pattern on the coated film. The light exposure may be carried out at a wavelength ranging from 200 to 450 nm at the exposure intensity of 10 to 100 mJ/cm². Then, the coated film thus patterned is subjected to post-bake at a temperature of 150 to 300° C. for 10 minutes to 5 hours to manufacture a desired insulating film.

The photosensitive resin composition of the present invention may produce a pattern having high planarity and high resolution during the formation of a coated film. Thus, it is suitable as the material for an organic insulating film used in a liquid crystal display, and preferably used for preparing an organic insulating film functioning as white pixels at the same time. Additionally, it is useful for the material of electronic parts or devices in various fields.

### MODE FOR THE INVENTION

Hereinafter, the present invention is explained in detail with reference to the following examples. The examples are intended to further illustrate the present invention without limiting its scope.

In the following examples, the weight average molecular weight is determined by gel permeation chromatography (GPC) using a polystyrene standard.

### Preparation Example 1: Preparation of Alkali-Soluble Resin (1-1)

A three-necked flask equipped with a condenser including a drying tube was placed on a stirrer with an automatic temperature controller. Then, 2 parts by weight of octyl mercaptan, 3 parts by weight of 2,2′-azobis(2,4-dimethyl valeronitrile), and 100 parts by weight of propylene glycol monomethyl ether acetate, based on 100 parts by weight of a monomer mixture were added to the flask, and nitrogen was charged thereto. In this case, the monomer mixture was composed of 22 mole % of methacrylic acid (MAA), 10 mole % of glycidyl methacrylate (GMA), 46 mole % of styrene (Sty), and 22 mole % of methyl methacrylate (MMA). Then, the temperature of the reaction mixture was elevated to 60° C. with slow agitation, and maintained for 5 hours for polymerization to obtain an alkali-soluble resin solution having a weight average molecular weight of 3,800.

### Preparation Examples 2 to 4: Preparation of Alkali-Soluble Resins (1-2) to (1-4)

Alkali-soluble resin solutions having a weight average molecular weight indicated in Table 1 below were obtained by the polymerization reaction according to the same method described in Preparation Example 1 with the exception that the polymerization time was extended.

TABLE 1

| | | | | | Weight |
|---|---|---|---|---|---|
| | | | | | average |
| | Monomer mixture components (mole %) | | | | molecular |
| | MAA | GMA | Sty | MMA | weight |
| Preparation | 22 | 10 | 46 | 22 | 3,800 |
| Ex. 1 (1-1) | | | | | |
| Preparation | 22 | 10 | 46 | 22 | 5,000 |
| Ex. 2 (1-2) | | | | | |
| Preparation | 22 | 10 | 46 | 22 | 7,167 |
| Ex. 3 (1-3) | | | | | |
| Preparation | 22 | 10 | 46 | 22 | 9,919 |
| Ex. 4 (1-4) | | | | | |

Photosensitive resin compositions of the following examples and comparative examples were prepared using the compounds prepared in the preparation examples.

The following compounds were used as other components.

Photopolymerizable compound (2-1): trimethylolpropane triacrylate (TMPTA)

Photopolymerization initiator (3-1): OXE-01 manufactured by BASF Co., Ltd.

Photopolymerization initiator (3-2): OXE-02 manufactured by BASF Co., Ltd.

Solvent (4-1): Propylene glycol monomethyl ether acetate manufactured by Chemtronics Co., Ltd.

Surfactant (5-1): FZ-2110 manufactured by Dow Corning Toray Silicon Co., Ltd.

Adhesion assisting agent (6-1): γ-isocyanatopropyltriethoxysilane manufactured by Shin-Etsu Co., Ltd.

### Example 1: Preparation of Photosensitive Resin Composition

Based on the solid content, 31.5 wt % of the alkali-soluble resin (1-1) obtained in Preparation Example 1, 60 wt % of the photopolymerizable compound (2-1), 6 wt % of the photopolymerization initiator (3-1), 2 wt % of the photopolymerization initiator (3-2), 0.2 wt % of the surfactant (5-1), and 0.3 wt % of the adhesion assisting agent (6-1) were mixed, and the solvent (4-1) was added thereto in an amount such that the total solid content of the mixture was 25 wt %. The mixture was admixed with a shaker for 2 hours to prepare a liquid-phase photosensitive resin composition.

### Examples 2 and 3, and Comparative Examples 1 to 4: Preparation of Photosensitive Resin Compositions

Photosensitive resin compositions were prepared in accordance with the same procedure as described in Example 1, with the exception that the kind and amount of the alkali-soluble resin, and the kind and amount of the photopolymerization compound were changed as indicated in Table 2 below.

TABLE 2

| | Components of composition (wt %, solid content basis) | | | | | | | | | | | |
|---|---|---|---|---|---|---|---|---|---|---|---|---|
| | Alkali- | | Photopolymerizable | | Photopolymerization | | | | | | Adhesion | |
| | soluble resin | | compound | | initiator | | | | Surfactant | | assisting agent | |
| Ex. 1 | 1-1 | 31.5 | 2-1 | 60 | 3-1 | 6 | 3-2 | 2 | 5-1 | 0.2 | 6-1 | 0.3 |
| Ex. 2 | 1-2 | 31.5 | 2-1 | 60 | 3-1 | 6 | 3-2 | 2 | 5-1 | 0.2 | 6-1 | 0.3 |
| Ex. 3 | 1-1 | 21.5 | 2-1 | 70 | 3-1 | 6 | 3-2 | 2 | 5-1 | 0.2 | 6-1 | 0.3 |
| Com. Ex. 1 | 1-3 | 51.5 | 2-1 | 40 | 3-1 | 6 | 3-2 | 2 | 5-1 | 0.2 | 6-1 | 0.3 |
| Com. Ex. 2 | 1-4 | 51.5 | 2-1 | 40 | 3-1 | 6 | 3-2 | 2 | 5-1 | 0.2 | 6-1 | 0.3 |
| Com. Ex. 3 | 1-1 | 61.5 | 2-1 | 30 | 3-1 | 6 | 3-2 | 2 | 5-1 | 0.2 | 6-1 | 0.3 |
| Com. Ex. 4 | 1-4 | 26.5 | 2-1 | 65 | 3-1 | 6 | 3-2 | 2 | 5-1 | 0.2 | 6-1 | 0.3 |

### Reference Example

Based on the solid content, 100 parts by weight of an alkali-soluble resin (benzyl methacrylate/methacrylic acid/methyl methacrylate, 40/30/30 mole %, Mw 20,000), 65 parts by weight of the photopolymerizable compound (2-1), 4 parts by weight of the photopolymerization initiator (3-1), 1.2 parts by weight of the photopolymerization initiator (3-2), 0.3 parts by weight of the surfactant (5-1), and 0.5 parts by weight of the adhesion assisting agent (6-1) were mixed, and 30 parts by weight of a blue pigment dispersant (containing 30 wt % of the solid content) and the solvent (4-1) added thereto, in an amount such that the total solid content of the mixture was 25 wt %. The mixture was admixed with a shaker for 2 hours to prepare a photosensitive resin composition.

With respect to the photosensitive resin compositions prepared in the examples and comparative examples, the following items were evaluated.

### Experimental Example 1: Evaluation of Planarity

Step (1) Manufacture of Lower Cured Film

The photosensitive resin composition obtained in the Reference Example was coated on a glass substrate and was pre-baked on a hot plate having a temperature of 100° C. for 100 seconds to form a pre-baked film in a thickness of 3 μm. On the pre-baked film, a mask having a line-spaced pattern wherein the lines having a thickness of 100 μm were disposed at intervals of 300 μm, was applied so that the distance from the substrate was 200 μm. Then, the film was exposed to light emitted from an aligner (model: MA6) in a wavelength range from 200 nm to 450 nm at the exposure intensity of 100 mJ/cm² based on a wavelength of 365 nm. The film was developed by an aqueous solution of 0.04 wt % KOH as a developing agent, at 23° C. via spray nozzles for 120 seconds. Subsequently, the film thus developed was heated in a convection oven at 230° C. for 30 minutes to produce a lower cured film in a thickness of 2.5 μm.

Step (2) Manufacture of Organic Insulating Film

Each of the photosensitive resin compositions obtained in the examples and comparative examples was coated on the lower cured film by spin coating. The coated substrate was pre-baked on a hot plate having a temperature of 105° C. for 90 seconds to form a pre-baked film in a thickness of about 5 μm. The pre-baked film was exposed to light at the exposure intensity of 20 mJ/cm² based on a wavelength of 365 nm with the same aligner used for forming the previous pre-baked film for a certain time period. Subsequently, the film thus obtained was heated in a convection oven at 230° C. for 30 minutes to produce a cured film (organic insulating film).

Step (3) Measure of Planarity (Height Difference)

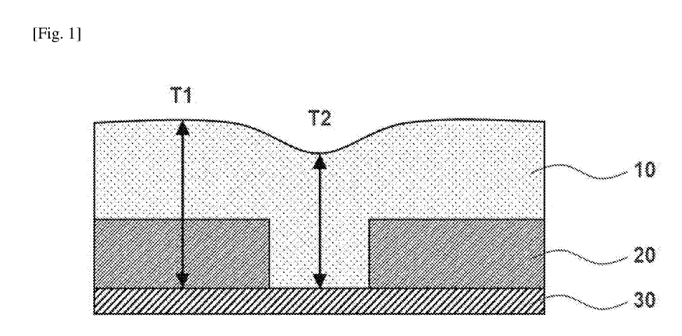

Referring to FIG. 1, a lower cured film (20) was formed on a substrate (30) by Step (1), and an organic insulating film (10) was formed on the lower cured film (20) by Step (2). In addition, due to the line-spaced pattern formed in the lower cured film (20), a region where the lower cured film (20) was formed and a region where the lower cured film (20) was not formed, were simultaneously present on the surface of the substrate (30). In this case, the height (T2) measured from the surface of the substrate (30) where the lower cured film (20) was not formed to the surface of the organic insulating film (10) may be smaller than the height (T1) measured from the surface of the substrate (30) where the lower cured film (20) was formed to the surface of the organic insulating film (10). Accordingly, the surface of the organic insulating film may not be planar.

The heights (T1 and T2) were measured using a three-dimensional surface measuring apparatus (SIS-2000 manufactured by SNU precision), and the planarity of the organic insulating film was calculated according to the following Mathematical Formula 1. The smaller the height difference value is, the better the planarity is.

Height Difference (Å)=T1−T2 [Mathematical Formula 1]

### Experimental Example 2: Evaluation of Resolution

Each of the compositions prepared in the examples and comparative examples was coated on a glass substrate by spin coating and the coated substrate was pre-baked on a hot plate having a temperature of 105° C. for 90 seconds to form a pre-baked film in a thickness of 4 μm. After disposing a mask having a square pattern with a 20 μm size so that the distance from the substrate was 10 μm, the pre-baked film was exposed to light for a certain time period at the exposure intensity of 20 mJ/cm² based on a wavelength of 365 nm with an aligner (model name: MA6) emitting light having a wavelength of 200 nm to 450 nm. Then, the film was developed using 2.38 wt % of a tetramethylammonium hydroxide aqueous developing agent through stream nozzles at 23° C. for 70 seconds. The film thus developed was then heated in a convection oven at 230° C. for 30 minutes to obtain a cured film.

The critical dimension (CD, line width, μm) of the hole pattern formed in the cured film using the mask having a square pattern with a 20 μm size was measured using a three-dimensional surface measuring apparatus (SIS-2000 manufactured by SNU precision), and the resolution (%) was calculated according to the following Mathematical Formula 2. The lower the resolution value (%) is, the better the resolution is.

Resolution (%)=[(20 μm−CD of hole pattern (μm))/20 μm]×100 [Mathematical Formula 2]

The resulting values obtained in the above experimental examples were evaluated according to the items indicated in Table 3 below, and are summarized in Table 4 below.

TABLE 3

| Score | Planarity (Height Difference, Å) | Resolution (%) |
|---|---|---|
| ⊚ | Less than 6,000 | Less than 50% |
| ◯ | 6,000 to less than 8,000 | 50 to less than 80% |
| X | 8,000 or more | 80% or more |

TABLE 4

| | Planarity | Resolution (%) |
|---|---|---|
| Ex. 1 | ⊚ | ◯ |
| Ex. 2 | ◯ | ◯ |
| Ex. 3 | ⊚ | ◯ |
| Com. Ex. 1 | X | ◯ |
| Com. Ex. 2 | X | ◯ |
| Com. Ex. 3 | X | ◯ |
| Com. Ex. 4 | ◯ | X |

As shown in Table 4, the compositions according to the examples exhibited good planarity and resolution. In contrast, the compositions according to the comparative examples exhibited poor planarity.

1. A photosensitive resin composition, comprising:
(1) an alkali-soluble resin having a weight average molecular weight of 1,000 to 5,000;
(2) a photopolymerizable compound; and
(3) a photopolymerization initiator;
wherein the components (1), (2), and (3) are included in amounts of 3 to 48 wt %, 50 to 95 wt %, and 0.5 to 15 wt %, respectively, based on a total solid content of the photosensitive resin composition.

2. The photosensitive resin composition of claim 1, wherein the alkali-soluble resin (1) is a copolymer comprising (1-1) a structural unit derived from an ethylenically unsaturated carboxylic acid, an ethylenically unsaturated carboxylic anhydride, or a mixture thereof, and (1-2) a structural unit derived from an ethylenically unsaturated compound containing an aromatic ring.

3. The photosensitive resin composition of claim 1, wherein the alkali-soluble resin (1) has a weight average molecular weight of 3,000 to 5,000.

4. The photosensitive resin composition of claim 1, wherein the photosensitive resin composition comprises the components (1), (2), and (3) in amounts of 8 to 38 wt %, 60 to 90 wt %, and 1 to 10 wt %, respectively, based on a total solid content of the photosensitive resin composition.

5. The photosensitive resin composition of claim 1, wherein the photopolymerization initiator is an oxime compound.

6. An organic insulating film formed using the photosensitive resin composition described in claim 1.
